(19) United States
(12) Patent Application Publication
(10) Pub. No.: US 2025/0095969 A1
(43) Pub. Date: Mar. 20, 2025

(54) SUBSTRATE PROCESSING APPARATUS, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventors: Takeshi Yasui, Toyama-shi (JP); Yukinori Aburatani, Toyama-shi (JP)

(73) Assignee: KOKUSAI ELECTRIC CORPORATION, Tokyo (JP)

(21) Appl. No.: 18/884,724

(22) Filed: Sep. 13, 2024

(30) Foreign Application Priority Data
Sep. 19, 2023 (JP) 2023-151023

(51) Int. Cl. H01J 37/32

(52) U.S. Cl. CPC H01J 37/32513; H01J 37/32522; H01J 37/32715; H01J 37/32926; H01J 2237/334; H01J 2237/338

(57) ABSTRACT

There is provided a technique that includes: a mounting table configured to be capable of mounting a substrate on the mounting table; a heater located above the mounting table and configured to radiate heat rays toward the substrate mounted on the mounting table to heat the substrate; a process container disposed below the heater and configured to accommodate the mounting table, wherein at least a portion of the process container, which is located adjacent to the heater, is made of opaque quartz; and a sealer configured such that transmission of heat rays reflected from the substrate to the sealer is suppressed by the at least a portion of the process container and airtightness between the process container and the heater is maintained by a seal.

### CROSS-REFERENCE TO RELATED APPLICATION

This application is based upon and claims the benefit of priority from Japanese Patent Application No. 2023-151023, filed on Sep. 19, 2023, the entire contents of which are incorporated herein by reference.

### TECHNICAL FIELD

The present disclosure relates to a substrate processing apparatus, a method of manufacturing a semiconductor device, and a recording medium.

### BACKGROUND OF THE INVENTION

In the related art, there are cases in which a lamp heater is provided on a top of a process container to perform a process for heating a substrate inside the process container.

However, when the substrate is heated, heat rays generated from the lamp heater may be reflected by the substrate, resulting in a seal provided at the top of the process container and that is heated and deteriorated.

### SUMMARY OF THE INVENTION

Some embodiments of the present disclosure provide a technique capable of suppressing deterioration of a seal.

According to embodiments of the present disclosure, there is provided a technique that includes: a mounting table configured to be capable of mounting a substrate on the mounting table; a heater located above the mounting table and configured to radiate heat rays toward the substrate mounted on the mounting table to heat the substrate; a process container disposed below the heater and configured to accommodate the mounting table, wherein at least a portion of the process container, which is located adjacent to the heater, is made of opaque quartz; and a sealer configured such that transmission of heat rays reflected from the substrate to the sealer is suppressed by the at least a portion of the process container and airtightness between the process container and the heater is maintained by a seal.

### BRIEF DESCRIPTION OF DRAWINGS

The accompanying drawings, which are incorporated in and constitute a part of the specification, illustrate embodiments of the present disclosure.

FIG. 1 is a schematic cross-sectional view of a substrate processing apparatus according to embodiments of the present disclosure.

FIG. 2 is a cross-sectional view showing a periphery of a ceiling of a process container of the substrate processing apparatus according to embodiments of the present disclosure.

FIG. 3 is a diagram showing a configuration of a controller (control means) of the substrate processing apparatus according to embodiments of the present disclosure.

FIG. 4 is a flowchart showing a substrate processing process according to embodiments of the present disclosure.

FIG. 5 is a diagram for explaining a state inside the process container in the substrate processing process according to embodiments of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

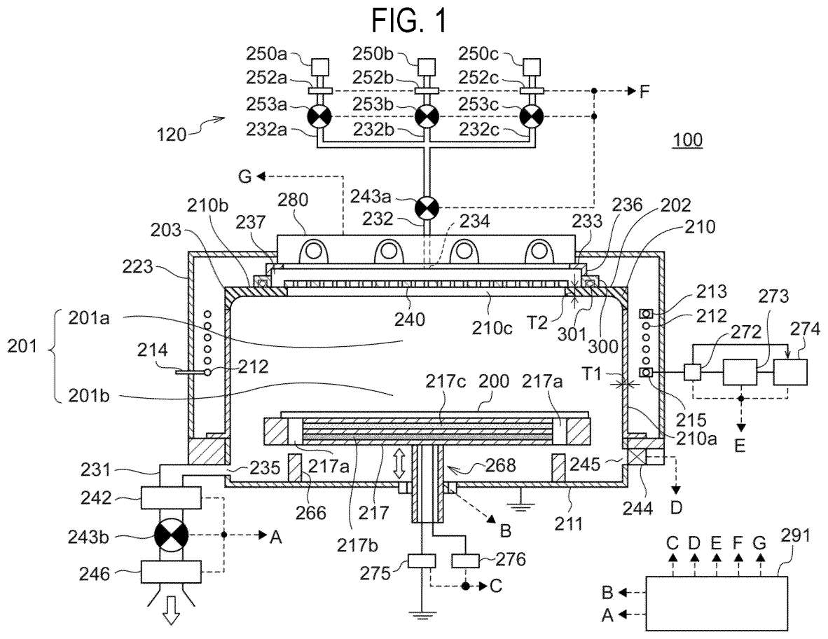

Hereinafter, embodiments of the present disclosure are described mainly with reference to FIGS. 1 to 5. All of the drawings used in the following description are schematic, and the dimensional relationships of respective elements, the ratios of respective elements, etc. illustrated in the drawings may not correspond to actual ones. Furthermore, the dimensional relationships of respective elements, the ratios of respective elements, etc. may not match among a plurality of drawings.

### (1) Configuration of Substrate Processing Apparatus

A substrate processing apparatus 100 according to embodiments of the present disclosure is described. The substrate processing apparatus according to the present embodiments is configured to mainly perform substrate processing on a film formed on a substrate surface or a base.

### <Process Chamber>

As shown in FIG. 1, the substrate processing apparatus 100 includes a process furnace 202 for performing plasma processing on a substrate 200. The process furnace 202 is provided with a process container 203 that constitutes a process chamber 201 and accommodates a susceptor 217 described below. The process container 203 includes a dome-shaped upper container 210, which is a first container, and a bowl-shaped lower container 211, which is a second container. The upper container 210 is placed over the lower container 211 to form the process chamber 201.

The process chamber 201 includes a plasma generation space 201a where a processing gas is excited into plasma, and a substrate process space 201b communicating with the plasma generation space 201a. The plasma generation space 201a is a space in a range where a resonant coil 212, which is an electrode and a coil, is provided therearound, and is a space where plasma is generated. The plasma generation space 201a refers to a space in the process chamber 201 that is formed above a lower end of the resonant coil 212 and below an upper end of the resonant coil 212. The substrate process space 201b is a space that communicates with the plasma generation space 201a and where the substrate 200 is processed. The substrate process space 201b is a space where the substrate is processed using plasma, and refers to a space formed below the lower end of the resonant coil 212. In the embodiments, a horizontal diameter of the plasma generation space 201a and a horizontal diameter of the substrate process space 201b are approximately the same. The configuration that forms the plasma generation space 201a is also called a plasma generation chamber, and the configuration that forms the substrate process space 201b is also called a substrate process chamber. The plasma generation space 201a may also be referred to as a plasma generation region in the process chamber 201. The substrate process space 201b may also be referred to as a substrate process region in the process chamber 201.

### <Susceptor>

As shown in FIG. 1, the substrate process space 201b in the process container 203 accommodates a susceptor 217 configured as a mounting table capable of mounting the substrate 200 thereon. The susceptor 217 is disposed below the lower end of the resonant coil 212 in the process chamber 201.

A susceptor heater 217b is integrally embedded inside the susceptor 217. The susceptor heater 217b is configured to be able to heat the substrate 200 when electric power is supplied thereto.

The susceptor 217 is electrically insulated from the lower container 211. An impedance adjustment electrode 217c is provided inside the susceptor 217 in order to further improve uniformity of a density of plasma generated on the substrate 200 mounted on the susceptor 217. The impedance adjustment electrode 217c is grounded via an impedance variator 275 serving as an impedance regulator.

The susceptor 217 is provided with a susceptor elevator 268 as a driver for raising and lowering the susceptor 217. The susceptor 217 is provided with through-holes 217a, and a bottom surface of the lower container 211 is provided with substrate lift pins 266. When the susceptor 217 is lowered by the susceptor elevator 268, the substrate lift pins 266 are configured to penetrate the through-holes 217a. The elevating operation of the susceptor 217 by the susceptor elevator 268 is controlled by a controller 291 described later. The controller 291 is configured to be capable of controlling the susceptor elevator 268 so that the substrate 200 is positioned below the plasma generation space 201a when the substrate 200 mounted on an upper surface (an example of a substrate mounting surface) of the susceptor 217 is being processed. By controlling the substrate processing position in this way, the substrate 200 is able to be raised from and lowered to most efficient positions for substrate processing.

A substrate mounting part according to the embodiments is mainly constituted by the susceptor 217, the susceptor heater 217b, and the impedance adjustment electrode 217c.

### <Process Container>

As shown in FIG. 1, the process container 203 is disposed below the lamp heater 280 to be described later, and is configured to accommodate the susceptor 217. The upper container 210 includes a side wall 210a and a ceiling 210b. The side wall 210a is cylindrical. The ceiling 210b extends along a circumferential direction of the side wall 210a and protrudes radially inward from an upper end of the side wall 210a. An opening 210c is formed at a center of the ceiling 210b.

A lower end of the ceiling 210b is disposed higher than the upper end of the resonant coil 212. That is, the ceiling 210b is disposed higher than the upper end of the resonant coil 212. Further, the ceiling 210b is disposed higher than the plasma generation space 201a.

The ceiling 210b is made of opaque quartz. Opaque quartz is a material in which air bubbles are dispersed, thus exhibiting a lower transmittance than transparent quartz and a higher reflectance than transparent quartz. In other words, opaque quartz is a material that possesses a lower thermal transmittance than transparent quartz, thus exhibiting a higher thermal insulating property and a higher heat shielding property than transparent quartz. That is, the ceiling 210b possesses a function of reflecting a portion of heat rays (also called electromagnetic wave or light) and shielding heat (suppressing the transmission of heat rays), more specifically, a function of reflecting a portion of the heat rays that are radiated from the lamp heater 280 and reflected by the substrate 200 and thus shielding heat (suppressing the transmission of heat rays).

The ceiling 210b may be made from opaque quartz of a natural material or opaque quartz of a synthetic material. The natural opaque quartz is less expensive than the synthetic opaque quartz. In addition, the synthetic opaque quartz contains less impurities than the natural opaque quartz.

By disposing the ceiling 210b higher than the plasma generation space 201a, it is possible to suppress etching of the ceiling 210b occurred by an influence of an electromagnetic field, etc. Therefore, even if the ceiling 210b is made of natural opaque quartz, it is possible to prevent or suppress generation of particles such as impurities or the like.

The side wall 210a is disposed below the upper end of the resonant coil 212. The side wall 210a is made of transparent quartz. Transparent quartz is a material with few air bubbles and impurities, thus exhibiting a higher transmittance than opaque quartz and a lower reflectance than opaque quartz. That is, the side wall 210a possesses a function of transmitting heat rays, more specifically, a function of transmitting an electromagnetic field generated by supplying radio-frequency power to the resonant coil 212, making it easier to generate plasma in the plasma generation space 201a.

That is, the upper container 210 is made of two types of materials with different transmittances (also called heat shielding properties or heat insulating properties).

The lower container 211 is made of, for example, aluminum (Al). A loading/unloading port 245 for loading and unloading the substrate 200 is formed in a lower portion of the lower container 211 and at a lower side of a side wall of the lower container 211. A gate valve 244 capable of opening and closing the loading/unloading port 245 is provided in the loading/unloading port 245. By loading and unloading the substrate 200 through the gate valve 244, it is possible to maintain the airtightness inside the process container 203.

### <Heater>

The lamp heater 280 is provided above the ceiling 210b. The lamp heater 280 is installed at a center of a lid 233. An outer periphery of the lid 233 is joined to a manifold 300. The lid 233 to which the lamp heater 280 is installed is joined to the ceiling 210b via the manifold 300.

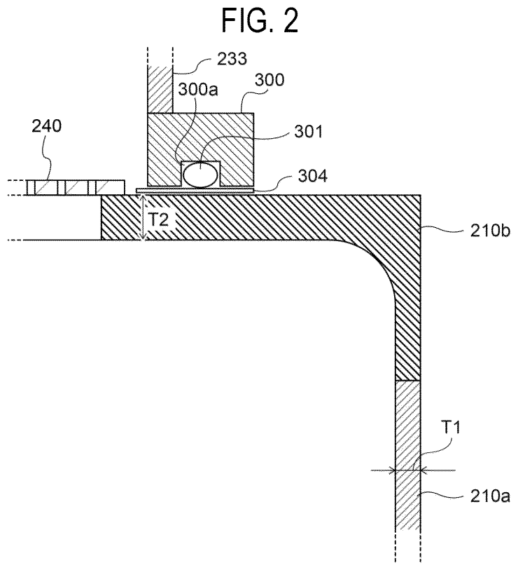

Specifically, as shown in FIGS. 1 and 2, the annular manifold 300 is joined to an upper portion of the ceiling 210b. More specifically, the ceiling 210b and the manifold 300 are fastened and fixed by, for example, screw members (not shown) so that a lower surface of the annular manifold 300 contacts an upper surface of the ceiling 210b.

An annular groove 300a is formed on the lower surface of the manifold 300. An O-ring 301, which is a seal and serves as a seal part, is fitted into the annular groove 300a. The O-ring 301 is in close contact with the upper surface of the ceiling 210b and the lower surface of the manifold 300 when the ceiling 210b and the manifold 300 are joined (fastened and fixed) to each other. There are no particular limitations on the O-ring 301 as long as it is an elastic body possessing heat resistance. For example, an O-ring made of a fluorine-based resin may be used as the O-ring 301.

As shown in FIG. 2, a transparent quartz sheet 304 is provided on the upper surface of the ceiling 210b, between the ceiling 210b and a lower end of the manifold 300. The transparent quartz sheet 304 is used as a sealing surface that brings the manifold 300 into contact with the ceiling 210b to perform sealing. In FIG. 2, there is shown a case in which the transparent quartz sheet 304 is provided on a portion of the upper surface of the ceiling 210b that comes into contact with the manifold 300. However, the present disclosure is not limited thereto. The transparent quartz sheet 304 may be provided on the entire upper surface of the ceiling 210b. Further, the transparent quartz sheet 304 may be formed by attaching transparent quartz to an upper end of the ceiling 210b and polishing a contact surface thereof with the lower end of the manifold 300. Also, the transparent quartz sheet 304 may be formed by disposing transparent quartz of a plate shape on the upper end of the ceiling 210b.

As described above, the ceiling 210b is made of opaque quartz and contains air bubbles, which makes it less airtight than transparent quartz. In the embodiments, the transparent quartz sheet made of transparent quartz, which possesses higher airtightness than opaque quartz, is provided between the ceiling 210b and the lower end of the manifold 300. This makes it possible to maintain airtightness between the upper end of the ceiling 210b and the lower end of the manifold 300. Thus, it is possible to maintain the airtightness inside the process container 203.

A sealer according to the embodiments is mainly constituted by the O-ring 301 and the transparent quartz sheet 304. A heater according to the embodiments is mainly constituted by the lamp heater 280 and the manifold 300. That is, the airtightness between the process container 203 and the heater, that is, the airtightness between the ceiling 210b and the heater, is maintained by the O-ring 301 and/or the transparent quartz sheet 304.

The lamp heater 280 is provided at a position above the susceptor 217 to face the upper surface of the susceptor 217. The lamp heater 280 is disposed above the process chamber 201, that is, outside the opening 210c of the upper container 210. The lamp heater 280 is configured to radiate heat rays (also called electromagnetic wave or light) from above the ceiling 210b toward the substrate 200 mounted on the susceptor 217 so as to heat the substrate 200. The lamp heater 280 is configured to efficiently heat the substrate 200 mounted on the susceptor 217.

Further, a thickness T2 of the ceiling 210b is set to be thicker than a thickness T1 of the side wall 210a. In other words, a difference between an inner periphery and an outer periphery of the upper container 210 is larger in the ceiling 210b than in the side wall 210a. By setting the thickness T2 of the ceiling 210b to be thicker than the thickness T1 of the side wall 210a, it is possible to further suppress the transmission of heat reflected by the substrate 200 in the ceiling 210b where the O-ring 301 is disposed, thus protecting the O-ring 301.

The thickness T1 of the side wall 210a is, for example, 5 to 10 mm, specifically 7 to 8 mm. If the thickness T1 of the side wall 210a is less than 5 mm, it may lead to an insufficient strength of the upper container 210. By setting the thickness T1 of the side wall 210a to be 5 mm or more, it is possible to secure the strength of the upper container 210. By setting the thickness T1 of the side wall 210a to be 7 mm or more, the strength of the upper container 210 may be made more sufficient. Further, if the thickness T1 of the side wall 210a exceeds 10 mm, most of the energy of the electromagnetic field generated by the resonant coil 212 may be converted into heat and lost in the side wall 210a. By setting the thickness T1 of the side wall 210a to be 10 mm or less, the energy of the electromagnetic field generated by the resonant coil 212 may be suppressed from being converted into heat and lost in the side wall 210a. By setting the thickness T1 of the side wall 210a to be 8 mm or less, it is possible to further suppress the energy of the electromagnetic field generated by the resonant coil 212 from being converted into heat and lost in the side wall 210a. Therefore, by setting the thickness T1 of the side wall 210a to be 5 to 10 mm, specifically 7 to 8 mm, it is possible to efficiently transmit the electromagnetic field and generate plasma in the plasma generation space 201a. Furthermore, if the thickness T1 of the side wall 210a exceeds 10 mm, a weight of the upper container 210 itself increases, and a load exerted on a surface of a lower end from the side wall 210a in contact with an upper end of the lower container 211 increases. By setting the thickness T1 of the side wall 210a to be 10 mm or less, it is possible to reduce the load on the surface in contact with the upper end of the lower container 211. By setting the thickness T1 of the side wall 210a to be 8 mm or less, it is possible to further reduce the load on the surface in contact with the upper end of the lower container 211. In the present disclosure, the expression of a numerical range such as “5 to 10 mm” means that the lower limit and the upper limit are included in the range. Thus, for example, “5 to 10 mm” means “5 mm or more and 10 mm or less.” The same applies to other numerical ranges.

The thickness T2 of the ceiling 210b is, for example, 12 to 20 mm, specifically 15 to 16 mm. If the thickness T2 of the ceiling 210b is less than 12 mm, the heat reflected from the substrate 200 may be substantially transmitted to an outside of the process container 203. If the thickness T2 of the ceiling 210b is 12 mm or more, the transmission of the heat reflected from the substrate 200 to the outside of the process container 203 may be suppressed. If the thickness T2 of the ceiling 210b is 15 mm or more, the transmission of the heat reflected from the substrate 200 to the outside of the process container 203 may be further suppressed. If the thickness T2 of the ceiling 210b exceeds 20 mm, the weight of the upper container 210 increases, causing the load exerted on the surface of the lower end from the side wall 210a in contact with the upper end of the lower container 211 to increase. By setting the thickness T2 of the ceiling 210b to be 20 mm or less, it is possible to reduce the load on the surface in contact with the upper end of the lower container 211. By setting the thickness T2 of the ceiling 210b to be 16 mm or less, it is possible to further reduce the load on the surface in contact with the upper end of the lower container 211. Therefore, by setting the thickness T2 of the ceiling 210b to be 12 to 20 mm, specifically 15 to 16 mm, it is possible to suppress the heating of the O-ring 301 by substantially preventing the heat reflected from the substrate 200 from being transmitted to the outside of the process container 203. This makes it possible to suppress deterioration of the O-ring 301.

### <Gas Supplier>

A gas supplier 120 that supplies processing gases to the plasma generation space 201a in the process container 203 is configured as follows.

A gas supply head 236 is provided above the process chamber 201, that is, on an upper portion of the upper container 210. The gas supply head 236 includes the cap-shaped lid 233, a gas introduction port 234, a buffer chamber 237, and a shower plate 240, and is configured to supply the processing gases into the process chamber 201.

A downstream end of a precursor gas supply pipe 232a that supplies a precursor gas, which is a processing gas, a downstream end of a reaction gas supply pipe 232b that supplies a reaction gas, which is a processing gas, and a downstream end of an inert gas supply pipe 232c that supplies an inert gas are connected to the gas introduction port 234 so as to join at a junction pipe 232. The precursor gas supply pipe 232a, the reaction gas supply pipe 232b, and the inert gas supply pipe 232c are also simply referred to as a gas supply pipe 232a, a gas supply pipe 232b, and a gas supply pipe 232c, respectively.

On the precursor gas supply pipe 232a, a precursor gas supply source 250a, a mass flow controller (MFC) 252a as a flow rate controller, and a valve 253a as an opening/closing valve are provided sequentially from an upstream side.

On the reaction gas supply pipe 232b, a reaction gas supply source 250b, an MFC 252b, and a valve 253b are provided sequentially from an upstream side.

On the inert gas supply pipe 232c, an inert gas supply source 250c, an MFC 252c, and a valve 253c are provided sequentially from an upstream side.

A valve 243a is installed on a downstream side of the junction pipe 232 where the precursor gas supply pipe 232a, the reaction gas supply pipe 232b, and the inert gas supply pipe 232c are joined together, and is connected to the gas introduction port 234. By opening and closing the valves 253a, 253b, 253c, and 243a, the precursor gas, the reaction gas, and the inert gas may be supplied into the process chamber 201 via the gas supply pipes 232a, 232b, and 232c, respectively, while regulating the flow rates of the respective gases with the MFCs 252a, 252b, and 252c.

The gas supplier 120 (gas supply system) according to the embodiments is mainly constituted by the precursor gas supply pipe 232a, the reaction gas supply pipe 232b, the inert gas supply pipe 232c, the MFCs 252a, 252b, and 252c, and the valves 253a, 253b, 253c, and 243a. The precursor gas supply source 250a, the reaction gas supply source 250b, and the inert gas supply source 250c may also be included in the gas supplier.

### <Exhaust Part>

A gas exhaust port 235 for exhausting the atmosphere in the process chamber 201 is provided on a side wall of the lower container 211. An upstream end of a gas exhaust pipe 231 is connected to the gas exhaust port 235. On the gas exhaust pipe 231, an APC (Auto Pressure Controller) valve 242 as a pressure regulator (pressure regulation part), a valve 243b as an opening/closing valve, and a vacuum pump 246 as a vacuum exhauster are installed sequentially from an upstream side.

An exhauster according to the present embodiments is mainly constituted by the gas exhaust port 235, the gas exhaust pipe 231, the APC valve 242, and the valve 243b. The vacuum pump 246 may also be included in the exhauster.

### <Plasma Generator>

A spiral resonant coil 212 is disposed on an outer periphery of the process chamber 201, i.e., outside the side wall 210a of the upper container 210, so as to surround the process chamber 201. In other words, the resonant coil 212 is disposed to wind around the outer periphery of the upper container 210 so that an outer periphery of a portion (region) of the process container 203 (upper container 210) corresponding to the plasma generation space 201a (an outer periphery of the plasma generation chamber) is surrounded. In other words, the resonant coil 212 is provided below the lower end of the ceiling 210b. By disposing the ceiling 210b made of opaque quartz above the resonant coil 212 in this way, it is possible to suppress the generation of particles by making it less susceptible to the influence of plasma.

A RF sensor 272, a radio-frequency power source 273 that supplies radio-frequency power to the resonant coil 212, and a matcher 274 that performs matching on an impedance or an output frequency of the radio-frequency power source 273 are connected to the resonant coil 212. The resonant coil 212 is disposed along an outer circumferential surface of the process container 203 at a distance from the outer circumferential surface, and is configured to generate an electromagnetic field in the process container 203 by supplying radio-frequency power (RF power) thereto. That is, the resonant coil 212 of the embodiments is an electrode of an inductively coupled plasma (ICP) type.

The radio-frequency power source 273 supplies radio-frequency power (RF power) to the resonant coil 212. The RF sensor 272 is provided on an output side of the radio-frequency power source 273 to monitor information on a traveling wave or a reflected wave of the supplied radio frequency. The reflected wave power monitored by the RF sensor 272 is inputted to the matcher 274. The matcher 274 controls the impedance of the radio-frequency power source 273 or the frequency of the outputted RF power based on the information on the reflected wave inputted from the RF sensor 272 so as to minimize the reflected wave.

A winding diameter, a winding pitch, and a number of turns of the resonant coil 212 are set such that the resonant coil 212 resonates at a certain wavelength in order to form a standing wave of a predetermined wavelength. In other words, an electrical length of the resonant coil 212 is set to a length equivalent to an integer multiple (1×, 2×, . . . ) of one wavelength at a predetermined frequency of the radio-frequency power supplied from the radio-frequency power source 273.

Both ends of the resonant coil 212 are electrically grounded, and at least one of the ends of the resonant coil 212 is grounded via a movable tap 213 in order to finely adjust the electrical length of the resonant coil 212. The other end of the resonant coil 212 is grounded via a fixed ground 214. The position of the movable tap 213 is regulated so that resonance characteristics of the resonant coil 212 are substantially equal to those of the radio-frequency power source 273. Furthermore, in order to finely adjust an impedance of the resonant coil 212, a power supply portion is formed between the grounded ends of the resonant coil 212 by a movable tap 215.

A shielding plate 223 is provided to shield the electric field outside the resonant coil 212. The shielding plate 223 is formed in a cylindrical shape, and is made of a conductive material such as an aluminum alloy or the like.

A plasma generator according to the embodiments is mainly constituted by the resonant coil 212, the RF sensor 272, and the matcher 274. The radio-frequency power source 273 may also be included in the plasma generator.

Now, the principle of plasma generation and the properties of the generated plasma in the apparatus according to the embodiments are described.

A plasma generation circuit formed by the resonant coil 212 is formed of a RLC parallel resonant circuit. In the plasma generation circuit, when plasma is generated, an actual resonant frequency varies slightly due to fluctuations in capacitive coupling between a voltage portion of the resonant coil 212 and the plasma, fluctuations in inductive coupling between the plasma generation space 201a and the plasma, an excited state of the plasma, and the like.

Therefore, in the embodiments, in order to compensate, from a power supply side, a resonance shift in the resonant coil 212 during plasma generation, the RF sensor 272 detects the reflected wave power generated from the resonant coil 212 during the plasma generation, and the matcher 274 corrects the output of the radio-frequency power source 273 based on the detected reflected wave power.

Specifically, the matcher 274 increases or decreases the impedance or the output frequency of the radio-frequency power source 273 so as to minimize the reflected wave power, based on the reflected wave power generated from the resonant coil 212 during the plasma generation, which is detected by the RF sensor 272.

With this configuration, in the resonant coil 212 of the embodiments, a radio-frequency power is supplied at the actual resonant frequency of the resonant coil including plasma (or a radio-frequency power is supplied so as to match the actual impedance of the resonant coil including plasma). Therefore, a standing wave is formed in which a phase voltage and an anti-phase voltage are always offset. When the electrical length of the resonant coil 212 is the same as the wavelength of the radio-frequency power, a highest phase current is generated at an electrical midpoint of the coil (node where the voltage is zero). Therefore, in the vicinity of the electrical midpoint, almost no capacitive coupling with the process chamber wall or the susceptor 217 is present, and doughnut-shaped induction plasma with an extremely low electrical potential is generated.

In the embodiments, the resonant coil 212, which is an ICP type electrode, is used as an electrode that generates an electromagnetic field in the process chamber 201 (plasma generation space 201a). However, the present disclosure is not limited to this configuration. For example, a cylindrical electrode of a modified magnetron type (MMT) may be used for this purpose.

### <Controller>

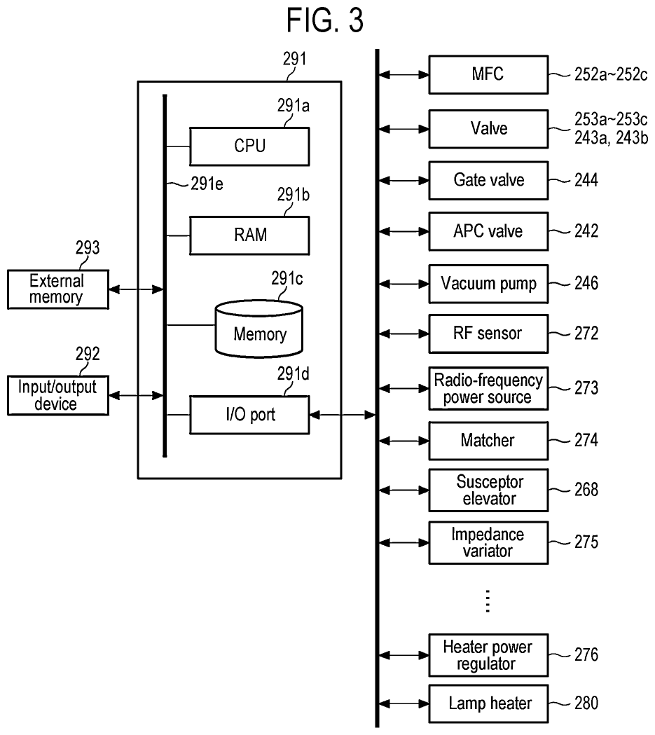

As shown in FIG. 3, the controller 291, which is a control unit (control means), is configured as a computer including a CPU (Central Processing Unit) 291a, a RAM (Random Access Memory) 291b, a memory 291c, and an I/O port 291d. The RAM 291b, the memory 291c, and the I/O port 291d are configured to be capable of exchanging data with the CPU 291a via an internal bus 291e. An input/output device 292, which is configured as, for example, a touch panel or a display, is connected to the controller 291.

The memory 291c is composed of, for example, a flash memory, a HDD (Hard Disk Drive), etc. The memory 291c stores, in a readable manner, control programs for controlling operations of the substrate processing apparatus, process recipes in which procedures and conditions, etc. of substrate processing to be described later are written, and the like. The process recipes are combinations of instructions that cause the controller 291 to execute respective procedures in a substrate processing process described later so that a predetermined result may be obtained. The process recipes function as programs. Hereinafter, the process recipes, the control programs, and the like may be collectively and simply referred to as “programs.” In addition, the term “programs” as used herein may refer to a case of including the process recipes, a case of including the control programs, or a case of including both. In addition, the RAM 291b is configured as a memory area (work area) in which the programs and data read by the CPU 291a are temporarily held.

The I/O port 291d is connected to the above-mentioned MFCs 252a to 252c, the valves 253a to 253c, the valves 243a and 243b, the gate valve 244, the APC valve 242, the vacuum pump 246, the RF sensor 272, the radio-frequency power source 273, the matcher 274, the susceptor elevator 268, the impedance variator 275, a heater power regulator 276, the lamp heater 280, and the like.

The CPU 291a is configured to read a control program from the memory 291c and execute the control program, and is configured to read a process recipe from the memory 291c in response to an input of an operation command from the input/output device 292. The CPU 291a is configured to, according to contents of the process recipe thus read, control the opening state regulation operation for the APC valve 242, the opening/closing operation of the valve 243b, and the start and stop of the vacuum pump 246, via the I/O port 291d and a signal line A. Further, the CPU 291a is configured to, according to the contents of the process recipe, control the raising/lowering operation of the susceptor elevator 268 via a signal line B. Further, the CPU 291a is configured to, according to the contents of the process recipe, control the supplied power amount regulation operation for the susceptor heater 217b (the temperature regulation operation) by the heater power regulator 276 and the impedance value regulation operation by the impedance variator 275, via a signal line C. Further, the CPU 291a is configured to, according to the contents of the process recipe, control the opening/closing operation of the gate valve 244 via a signal line D. Further, the CPU 291a is configured to, according to the contents of the process recipe, control the operations of the RF sensor 272, the matcher 274, and the radio-frequency power source 273 via a signal line E. Further, the CPU 291a is configured to, according to the contents of the process recipe, control the flow rate regulation operations for various gases by the MFCs 252a to 252c and the opening/closing operations of the valves 253a to 253c and 243a via a signal line F. Further, the CPU 291a is configured to, according to the contents of the process recipe, control the heating operation (temperature regulation operation) of the lamp heater 280 via a signal line G. The CPU 291a may also control the operations of device components other than those mentioned above.

The controller 291 may be configured by installing the above-mentioned program stored in an external memory (e.g., a magnetic tape, a magnetic disk such as a flexible disk or a hard disk, an optical disk such as a CD or a DVD, an optical magnetic disk such as a MO or the like, or a semiconductor memory such as a USB memory or a memory card) 293 into a computer. The memory 291c and the external memory 293 are configured as non-transitory computer-readable recording media on which a program is recorded. Hereinafter, these are collectively and simply referred to as “recording medium.” When the term “recording medium” is used herein, it may refer to a case of including the memory 291c, a case of including the external memory 293, or a case of including both. Further, the program may be provided to the computer by using a communication means such as the Internet or a dedicated line, instead of using the external memory 293.

### (2) Substrate Processing Process

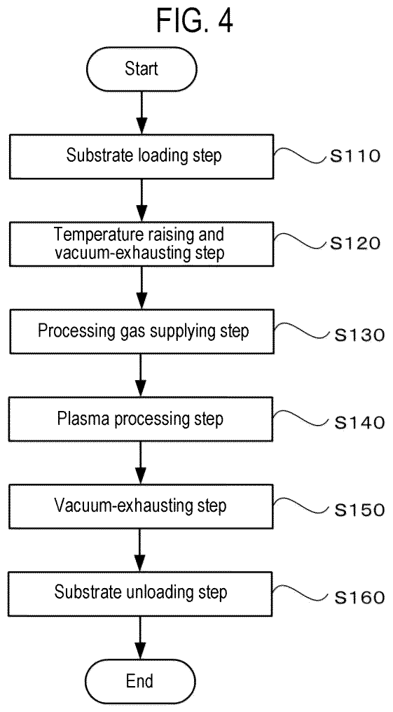

Next, a substrate processing process according to the embodiments of the present disclosure is described mainly with reference to FIG. 4. FIG. 4 is a flowchart showing the substrate processing process according to the present embodiments. The substrate processing process according to the present embodiments is performed by the above-mentioned substrate processing apparatus 100 as one of processes of manufacturing a semiconductor device such as a flash memory or the like, for example. In the following description, the operation of each part constituting the substrate processing apparatus 100 is controlled by the controller 291.

The term “substrate” used herein may refer to “a substrate itself” or “a stacked body of a substrate and a predetermined layer or film formed on a surface of the substrate.” The term “a surface of a substrate” used herein may refer to “a surface of a substrate itself” or “a surface of a predetermined layer or the like formed on a substrate.” The expression “a predetermined layer is formed on a substrate” used herein may mean that “a predetermined layer is directly formed on a surface of a substrate itself” or that “a predetermined layer is formed on a layer or the like formed on a substrate.” The term “wafer” used herein may be synonymous with the term “substrate.”

### (Substrate Loading Step S110)

First, the susceptor elevator 268 lowers the susceptor 217 to a transfer position of the substrate 200, and causes the substrate lift pins 266 to penetrate the through-holes 217a of the susceptor 217. Next, the gate valve 244 is opened, and the substrate 200 is loaded into the process chamber 201 from a vacuum transfer chamber adjacent to the process chamber 201 by using a substrate transferer (not shown). The loaded substrate 200 is supported in a horizontal posture on the substrate lift pins 266 protruding from the surface of the susceptor 217. Then, the gate valve 244 is closed, and the susceptor elevator 268 raises the susceptor 217 to the substrate processing position. The substrate 200 is mounted on the upper surface of the susceptor 217. At this time, the substrate 200 mounted on the susceptor 217 is disposed to be located in the substrate process space 201b below the lower end of the resonant coil 212. (Temperature Raising and Vacuum-Exhausting Step S120)

Then, a temperature of the substrate 200 loaded into the process chamber 201 is raised.

The susceptor heater 217b is preheated, and the lamp heater 280 is turned on (ON) to raise the temperature of the substrate 200 held on the susceptor 217 to a predetermined value within a range of, for example, 700 to 900 degrees C. At this time, the light emitted from the lamp heater 280 for heating the substrate 200 is mostly reflected into the process chamber 201 without being absorbed by the upper container 210 as described later, and is absorbed by the substrate 200, thereby heating the substrate 200 efficiently.

During the temperature raising for the substrate 200, the vacuum pump 246 vacuum-exhausts the process chamber 201 through the gas exhaust pipe 231 to set a pressure in the process chamber 201 to a predetermined value. The vacuum pump 246 is operated at least until the substrate unloading step S160 described later is completed.

### (Processing Gas Supply Step S130)

Next, the supply of a precursor gas and a reaction gas as processing gases is started. Specifically, the valves 253a and 253b are opened, and the supply of the precursor gas and the reaction gas into the process chamber 201 is started while controlling the flow rates thereof by the MFCs 252a and 252b.

Moreover, the opening state of the APC valve 242 is regulated to control the exhaustion of the inside of the process chamber 201 so that the pressure in the process chamber 201 becomes a predetermined value. In this manner, while appropriately exhausting the process chamber 201, the supply of the precursor gas and the reaction gas is continued until the end of the plasma processing step S140 described later.

As the precursor gas, for example, an oxygen (O)-containing gas may be used. As the O-containing gas, for example, an oxygen (O₂) gas, a nitrous oxide (N₂O) gas, a nitric oxide (NO) gas, a nitrogen dioxide (NO₂) gas, an ozone (O3) gas, a water vapor (H₂O gas), a carbon monoxide (CO) gas, a carbon dioxide (CO₂) gas, or the like may be used. As the O-containing gas, one or more of these gases may be used.

In addition, as the reaction gas, for example, a hydrogen (H)-containing gas may be used. As the H-containing gas, for example, a hydrogen (H₂) gas, a deuterium (D₂) gas, a H₂O gas, an ammonia (NH₃) gas, or the like may be used. As the H-containing gas, one or more of these gases may be used. When the H₂O gas is used as the O-containing gas, a gas other than the H₂O gas may preferably be used as the H-containing gas, and when the H₂O gas is used as the H-containing gas, a gas other than the H₂O gas may preferably be used as the O-containing gas.

As the inert gas, for example, a nitrogen (N₂) gas may be used. In addition, a rare gas such as an argon (Ar) gas, a helium (He) gas, a neon (Ne) gas, a xenon (Xe) gas, or the like may be used as the inert gas. One or more of these gases may be used as the inert gas. (Plasma Processing Step S140)

After the pressure in the process chamber 201 is stabilized, the application of radio-frequency power from the radio-frequency power source 273 to the resonant coil 212 is started. As a result, a radio-frequency electromagnetic field is formed in the plasma generation space 201a to which the precursor gas and the reaction gas are supplied. By the radio-frequency electromagnetic field, a donut-shaped induction plasma with a highest plasma density is excited at a height position corresponding to an electrical midpoint of the resonant coil 212 in the plasma generation space 201a. For example, when the O-containing gas is used as the precursor gas and the H-containing gas is used as the reaction gas, the processing gas containing the plasma-state O-containing gas and H-containing gas is plasma-excited and dissociated. Reaction species such as O-radicals (O-active species) and O ions containing O, or H-radicals (H-active species) and H ions containing H are generated.

Radicals and unaccelerated ions generated by the induced plasma are uniformly supplied to the surface of the substrate 200 held on the susceptor 217 in the substrate process space 201b. For example, when the O-containing gas is used as the precursor gas and the H-containing gas is used as the reaction gas, the supplied radicals and ions react uniformly with, for example, a silicon layer on the surface, to modify the silicon layer into a silicon oxide layer with good step coverage.

Thereafter, after a predetermined processing time, for example, 10 to 300 seconds, is elapsed, the power output from the radio-frequency power source 273 is stopped to stop the plasma discharge in the process chamber 201. Furthermore, the valves 253a and 253b are closed to stop the supply of the precursor gas and the reaction gas into the process chamber 201. This completes the plasma processing step S140. In the present disclosure, the processing time means the time during which the processing continues. This also applies to the following description.

### Vacuum-Exhausting Step S150)

After the supply of the precursor gas and the reaction gas is stopped, the inside of the process chamber 201 is vacuum-exhausted via the gas exhaust pipe 231. Thus, the precursor gas and the reaction gas in the process chamber 201, and an exhaust gas generated by the reaction of these gases, are discharged to an outside of the process chamber 201. Thereafter, the opening state of the APC valve 242 is regulated to regulate the pressure in the process chamber 201 to the same pressure as that of the vacuum transfer chamber (not shown) adjacent to the process chamber 201. The vacuum transfer chamber is the destination to which the substrate 200 is transferred.

### (Substrate Unloading Step S160)

After the pressure in the process chamber 201 reaches a predetermined pressure, the susceptor 217 is lowered to the transfer position of the substrate 200, and the substrate 200 is supported on the substrate lift pins 266. Then, the gate valve 244 is opened, and the substrate 200 is unloaded from the process chamber 201 using the substrate transferer. This completes the substrate processing process according to the embodiments.

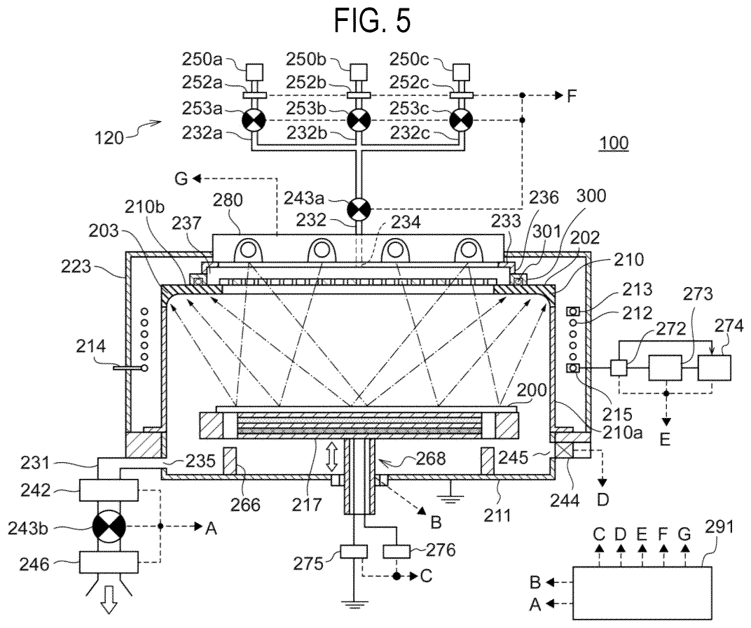

FIG. 5 is a diagram for explaining a state inside the process container 203 in the above-mentioned substrate processing process.

As shown in FIG. 5, the inside of the process container 203 is heated mainly by the radiant heat from the lamp heater 280, the reflected heat from the substrate 200, the heat in the plasma generation space 201a during plasma generation, and the heat of the susceptor heater 217b. That is, heat sources of heat rays are mainly the lamp heater 280, the plasma generation space 201a, and the susceptor heater 217b. In the embodiments, the substrate 200 is heated by the lamp heater 280 and the susceptor heater 217b, and the processing gas is excited into plasma by the plasma generator to process the heated substrate 200. This makes it possible to efficiently heat the substrate 200.

In this regard, if the ceiling 210b is made of transparent quartz, the heat rays irradiated from the lamp heater 280 and reflected by the substrate 200 may pass through the transparent quartz and may heat the O-ring 301. That is, as the substrate temperature is increased during substrate processing, a temperature of the O-ring 301 may also increase and may exceed a heat resistance temperature of the O-ring 301, for example, 300 degrees C.

In the above-described embodiments, since the ceiling 210b is made of opaque quartz, it is possible to suppress the transmission of heat rays emitted from the lamp heater 280 and reflected by the substrate 200 on the susceptor 217, whereby the heat reflected by the substrate 200 may be confined inside the process container 203.

That is, the heat rays reflected by the substrate 200 are suppressed from being directly irradiated onto the O-ring 301, and rise in a temperature of the ceiling 210b due to the reflected heat confined in the process container 203 is suppressed, thereby preventing the O-ring 301 from being indirectly heated. This makes it possible to suppress the temperature of the O-ring 301 disposed on an upper portion of the ceiling 210b to 260 degrees C. or lower, which is lower than the heat resistance temperature of the O-ring 301, for example, 300 degrees C. As a result, it becomes possible to suppress damage, deterioration, etc. of the O-ring 301 caused by the heating by the lamp heater 280.

In addition, in the above-described embodiments, since the side wall 210a is made of transparent quartz, it is possible to transmit the electromagnetic field generated by supplying radio-frequency power to the resonant coil 212. This makes it easier to generate plasma in the plasma generation space 201a.

In addition, in the embodiments, when processing the substrate 200, the controller 291 controls the susceptor elevator 268 so that the substrate 200 is positioned below the lower end of the resonant coil 212. Therefore, even if the substrate 200 is positioned away from the lamp heater 280 across the plasma generation region, the substrate 200 is possible to be efficiently heated by the heat reflected by the opaque quartz that constitutes the upper container 210.

### Other Embodiments of the Present Disclosure

In the above-described embodiments, the entire ceiling 210b is made of opaque quartz. However, the present disclosure is not limited thereto. For example, at least a portion of the ceiling 210b adjacent to the manifold 300 may be made of opaque quartz. Further, at least a portion of the ceiling 210b above the upper end of the resonant coil 212 may be made of opaque quartz. Also in such embodiments, the same effects as those of the above-described embodiments may be obtained.

In the above-described embodiments, there is described the case where the entire side wall 210a is made of transparent quartz. However, the present disclosure is not limited thereto. For example, at least portion of the side wall 210a corresponding to the range from the upper end to the lower end of the resonant coil 212 constituting the plasma generation part may be made of transparent quartz. In other words, a portion of the upper container 210 corresponding to the plasma generation space 201a (i.e., constituting the plasma generation space 201a) may be made of transparent quartz. In such embodiments, the same effects as those of the above-described embodiments may be obtained. In addition, in such embodiments, since a portion of the upper container 210 other than the portion corresponding to the plasma generation space 201a is made of opaque quartz, it is possible to suppress the transmission of heat to the outside of the process container 203, thus efficiently performing the substrate processing.

In the above-described embodiments, there is described the example in which the oxidation process on the substrate surface is performed using plasma. However, the present disclosure may also be applied to a nitriding process using a nitrogen-containing gas as a processing gas. The present disclosure is not limited to the nitriding process and the oxidation process but may also be applied to any technique that performs a process on a substrate by using plasma. For example, the present disclosure may be applied to a modifying process for a film formed on a substrate surface, a doping process, a reducing process for an oxide film, an etching process for the film, and an ashing process for a resist, performed by using plasma.

The above-described embodiments and modifications may be used in appropriate combination. The processing procedures and processing conditions in this case may be the same as, for example, those of the above-described embodiments and modifications.

Although the present disclosure is described in detail with respect to specific embodiments and modifications, it will be apparent to those skilled in the art that the present disclosure is not limited to such embodiments and modifications, and that various other embodiments may be adopted within the scope of the present disclosure.

According to the present disclosure in some embodiments, it is possible to suppress deterioration of a seal.

While certain embodiments are described, these embodiments are presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a mounting table configured to be capable of mounting a substrate on the mounting table;
a heater located above the mounting table and configured to radiate heat rays toward the substrate mounted on the mounting table to heat the substrate;
a process container disposed below the heater and configured to accommodate the mounting table, wherein at least a portion of the process container, which is located adjacent to the heater, is made of opaque quartz; and
a sealer configured such that transmission of heat rays reflected from the substrate to the sealer is suppressed by the at least a portion of the process container and airtightness between the process container and the heater is maintained by a seal.

2. The substrate processing apparatus of claim 1, wherein the process container includes at least a ceiling and a side wall, and
wherein the ceiling is made of opaque quartz.

3. The substrate processing apparatus of claim 2, wherein the opaque quartz is a natural material.

4. The substrate processing apparatus of claim 2, wherein the opaque quartz is a synthetic material.

5. The substrate processing apparatus of claim 2, wherein the side wall is made of transparent quartz.

6. The substrate processing apparatus of claim 1, wherein a sealing surface is provided between the process container and the heater, and the sealer is in contact with the process container and the heater at the sealing surface.

7. The substrate processing apparatus of claim 2, wherein the sealer includes a transparent quartz sheet and maintains airtightness between the ceiling and the heater.

8. The substrate processing apparatus of claim 2, wherein the seal is an O-ring and is configured to maintain airtightness between the ceiling and the heater.

9. The substrate processing apparatus of claim 8, wherein the ceiling is configured to suppress transmission of the heat rays reflected by the substrate and to prevent the O-ring from being heated by the heat rays.

10. The substrate processing apparatus of claim 1, wherein a plasma generation space in which a processing gas is plasma-excited and a substrate process space communicating with the plasma generation space are configured by the process container, and
wherein the substrate processing apparatus further comprises:
a gas supplier configured to supply the processing gas to the plasma generation space; and
a plasma generator provided on an outer periphery of the process container so as to surround the plasma generation space and configured to excite the processing gas into plasma.

11. The substrate processing apparatus of claim 1, wherein the heater includes a lamp heater.

12. The substrate processing apparatus of claim 1, further comprising, at a lower portion of the process container:
a loading/unloading port configured to load and unload the substrate;
a driver configured to raise and lower the mounting table; and
a controller configured to be capable of controlling the driver to raise and lower the mounting table to load and unload the substrate.

13. The substrate processing apparatus of claim 10, wherein a heat source of the heat rays is the heater.

14. The substrate processing apparatus of claim 10, wherein a heat source of the heat rays is the plasma generation space.

15. The substrate processing apparatus of claim 2, wherein a thickness of the ceiling is thicker than a thickness of the side wall.

16. The substrate processing apparatus of claim 10, wherein the process container includes at least a ceiling and a side wall, and
wherein the ceiling is made of opaque quartz, and a lower end of the ceiling is located above an upper end of the plasma generator.

17. The substrate processing apparatus of claim 16, further comprising:
a driver configured to raise and lower the mounting table; and
a controller configured to be capable of controlling the driver so that the substrate mounted on the mounting table is positioned below a lower end of the plasma generator.

18. A method of manufacturing a semiconductor device by using a substrate processing apparatus that includes a mounting table configured to be capable of mounting a substrate on the mounting table, a heater located above the mounting table and configured to radiate heat rays toward the substrate mounted on the mounting table to heat the substrate, a process container disposed below the heater, configured to accommodate the mounting table, wherein at least a portion of the process container, which is located adjacent to the heater, is made of opaque quartz, and a sealer configured such that transmission of heat rays reflected from the substrate to the sealer is suppressed by the at least a portion of the process container and airtightness between the process container and the heater is maintained by a seal, the method comprising:
mounting the substrate on the mounting table; and
heating the substrate by the heater.

19. A non-transitory computer-readable recording medium storing a program that causes, by a computer, a substrate processing apparatus, which includes a mounting table configured to be capable of mounting a substrate on the mounting table, a heater located above the mounting table and configured to radiate heat rays toward the substrate mounted on the mounting table to heat the substrate, a process container disposed below the heater, configured to accommodate the mounting table, wherein at least a portion of the process container, which is located adjacent to the heater, is made of opaque quartz, and a sealer configured such that transmission of heat rays reflected from the substrate to the sealer is suppressed by the at least a portion of the process container and airtightness between the process container and the heater is maintained by a seal, to perform a process comprising:
mounting the substrate on the mounting table; and
heating the substrate by the heater.
